(19) United States
(12) Patent Application Publication
(10) Pub. No.: US 2014/0352756 A1
(43) Pub. Date: Dec. 4, 2014

(54) SOLAR BALLOON PHOTOVOLTAIC ARRAY

(71) Applicants: Vinh Minh Glisttenmeer Lam, Hayward, CA (US); Ethan Lam, Fremont, CA (US); Megan Lam, Fremont, CA (US); Victor Lam, Fremont, CA (US)

(72) Inventors: Vinh Minh Glisttenmeer Lam, Hayward, CA (US); Ethan Lam, Fremont, CA (US); Megan Lam, Fremont, CA (US); Victor Lam, Fremont, CA (US)

(21) Appl. No.: 13/907,870

(22) Filed: Jun. 1, 2013

(51) Int. Cl. H01L 31/042

(52) U.S. Cl. CPC H01L 31/0422; H02S 20/00
USPC 136/245

(57) ABSTRACT

The Solar Balloon Photovoltaic Array is comprised of a solar balloon supporting and lifting an array of very thin, light weight, and flexible solar photovoltaic sheet array which is attached to an electrical wire cord tethered to the solar balloon at one end, and securely tied to a structure on the ground surface at the terminal output end. The solar balloon is deployed into the atmosphere by the heating of the air inside the solar balloon by direct sunlight as well as by an electrical heating element inside the solar balloon. The solar balloon is first partially inflated on the ground surface and then fully inflated by solar energy heating the air inside the balloon, which fully inflates the solar balloon to provide sufficient buoyancy lifting force to lift the solar array into the sky, forming a vertical solar photovoltaic array to provide solar generated electricity for household consumption.

### BACKGROUND OF THE INVENTION

1. Field of the Invention

This invention relates to the field of photovoltaic solar cell array.

2. Description of the Prior Art

### REFERENCES CITED

| Patent or Application | | | |
|---|---|---|---|
| Number | Date | Inventor | Field |
| U.S. Pat. No. 3,337,162 | Aug. 22, 1967 | Bauserman | 244/31 |
| U.S. Pat. No. 3,565,368 | Feb. 23, 1971 | Woodcroft Ave. et al | 244/31 |
| U.S. Pat. No. 4,174,082 | Nov. 13, 1979 | Eshoo | 244/31 |
| U.S. Pat. No. 4,361,297 | Nov. 20, 1982 | Pommereau et al | 244/31 |
| U.S. Pat. No. 4,364,532 | Dec. 21, 1982 | Stark | 244/30 |
| U.S. Pat. No. 6,371,409 | Apr. 16, 2002 | Steele | 244/30 |
| 20120235410 | Sep. 20, 2012 | Serrano | 290/50 |

There is a need in our world for clean energy. Solar energy is the cleanest and it is freely available. However, adopting photovoltaic solar energy technology on a wide scale is limited by many important factors. The most important factors are cost, surface area limitation on rooftops, and difficulty and complexity of mounting the prior art's solar panel. Our invention seeks to reduce the effects of these limiting factors by creating a new type of solar photovoltaic array. Specifically, our invention seeks to satisfy the enormous demands and needs for clean and renewable energies in the third world countries and developing world countries. To satisfy the energy needs of these regions, certain criteria must be met. First, the solar photovoltaic array has to be easily stored and transportable. Secondly, the solar photovoltaic array must be easily mounted and installed at any location onto any structure. Third, the solar photovoltaic array should occupy a small horizontal ground surface, since poor people cannot afford to own land in these regions. Fourth, the number of components in the balance of system has to be small to reduce the cost and weight of the entire system. Fifth, the entire solar photovoltaic array has to be economically affordable and low cost. Our invention, the Solar Balloon Photovoltaic Array, satisfies all these criteria.

The prior art's solar panels are quite heavy, cumbersome, expensive, and occupy enormous area on rooftops. The number of components in the balance of system of these prior art's solar panels is quite numerous. Many components are required to mount the solar panels onto the rooftop, increasing the cost of material as well as the cost of labor. Furthermore, the limited area on rooftop restricts the number of solar panels that can be mounted onto rooftop. There is a need for major improvements to the prior art in this field.

The prior art has invented a kind of balloon that are powered by solar energy. These solar balloons are heated by direct sunlight, increasing the temperature of the air inside the balloon envelope, which provides a buoyancy lifting force for the balloon according to the Archimedes Principle. The construction of these solar balloons is simple, and once airborne, the increasing amount of sunlight incident onto the balloon provides for an increasing amount of lift generated by the increasing temperature inside the balloon. This lifting force created by the solar heating of the air inside the balloon can be harnessed to lift objects. Currently, in the prior art, solar balloons have not been used to lift solar panels, for the obvious reason that current solar panels are too heavy to be supported by solar balloons. Our invention is novel and non-obvious in that we propose to use solar balloons to lift very lightweight, flexible, and very thin solar photovoltaic array, a combination that has never been seen before in the prior art.

The prior art has also proposed using multiple floating devices, such as airships, to lift heavy flat solar panels. These floating devices are powered by means that are not derived from solar energy. This prior art proposed using such floating devices to lift a few flat solar panels that are quite heavy, making such proposals impractical and uneconomical. The reason for such uneconomical and impractical proposal is obvious because lightweight solar panels did not exist until only very recently.

The prior art has very recently produced very lightweight, thin and flexible solar photovoltaic sheets. For example, Alta Devices Inc in Sunnyvale, Calif., has produced this kind of very light weight, thin and flexible solar photovoltaic sheets. It is foreseeable that other companies in the future will create similarly light weight, thin and flexible solar photovoltaic sheets. These thin flexible photovoltaic sheets are a few millimeters in thickness and are very light weight as well as durable. They are extremely efficient in converting sunlight into electricity, with efficiency reaching 28% for the GaAs thin film photovoltaic sheets made by Alta Devices Inc, which has a company website at http://www.altadevices.com/. It is expected that as technology improve, these solar photovoltaic thin film sheets will become even more efficient and less expensive to manufacture. Other companies using other materials will be able to manufacture similarly lightweight, flexible and thin solar photovoltaic sheets in the future. As more efficient and less expensive solar photovoltaic sheets become available, we will incorporate them into our invention.

Our invention will combine the prior arts including recent development of never before seen very light weight and thin solar photovoltaic flexible sheets in a new way to create a new kind of solar photovoltaic array. Specifically, we propose to use solar balloons as floating platforms to lift an array of very lightweight flexible solar photovoltaic sheets into the atmosphere. This is a novel and non-obvious combination of prior art technologies that has never been created before. Our invention will reduce the number of components in the balance of system, decrease the cost of materials, reduce the complexity of mounting, installing, and deploying the solar photovoltaic array, and reduce the cost of labor in transporting, storing, and installing the solar photovoltaic array. Our invention can be installed anywhere, on any structure, and in any environment with the most minimal cost of any solar photovoltaic technologies in existence today.

### SUMMARY OF THE INVENTION

Our invention comprises of a solar balloon tethered to an array of very lightweight, thin, and flexible solar photovoltaic sheets. Many of these solar photovoltaic sheets are attached to a very long electrical wire cord that is attached to the solar balloon. The very long electrical wire cord also conducts the electricity generated by the flexible solar photovoltaic sheets array to the electrical outlet terminal at one end of the electrical cord. Sunlight will heat the air inside the solar balloon to provide lift. In turn, the solar balloon will lift an array of thin flexible solar photovoltaic sheets into the atmosphere. One end of the electrical cord will be attached to a structure on the ground. The electricity generated by the solar photovoltaic sheets will be conducted along this electrical cord to the terminal output at one end of the cord and to the heating element inside the balloon. Some of the electricity generated by the solar photovoltaic sheets will be channeled into a heating element inside the solar balloon to help heat the air inside the solar balloon to provide additional buoyancy lift. The remainder of the electricity generated will be channeled to the electrical terminal output to provide electrical power for household appliances, charging battery, or the electrical grid.

### BRIEF DESCRIPTION OF FIGURES

FIG. 1 depicts an isometric view of the solar balloon supported array of flexible solar photovoltaic sheets. The very lightweight, thin, and flexible photovoltaic sheets 3 are mechanically and electrically attached along an electrical wire cord 2. The electrical terminal output 4 is shown at one end of the electrical cord. The electrical wire cord 2 also serves as the balloon string to attach the balloon to a structure on the ground surface using the extended end at the terminal output 4.

FIG. 2 depicts a front view of the solar balloon photovoltaic array. The heating element 5 increases the temperature of the air inside the solar balloon.

FIG. 3 shows a cross section of the solar balloon. The heating element 5 increases the temperature of the air 9 inside the solar balloon. The dark color outer surface 6 of the balloon envelope absorbs sunlight to heat up the air inside the balloon. The balloon envelope 7 is made of a polymeric material such as ripstop nylon or dacron (a polyester). The inner surface 8 of the solar balloon has a reflective surface such as an aluminum coating. This reflective inner surface 8 helps trap the infrared radiation and heat inside the solar balloon to maintain the hot temperature of the air inside the balloon in order to sustain the buoyancy lifting force.

FIG. 4 depicts a close-up view of the solar photovoltaic sheets array 3. The individual photovoltaic sheets 3 are oriented in various directions, angles, and orientation in order to absorb sunlight from any direction.

FIG. 5 depicts a close-up view of the solar balloon, showing how the solar balloon 1 is tethered to the electrical wire cord 2, which carry the array of solar photovoltaic sheets 3.

### DETAILED DESCRIPTION OF THE INVENTION

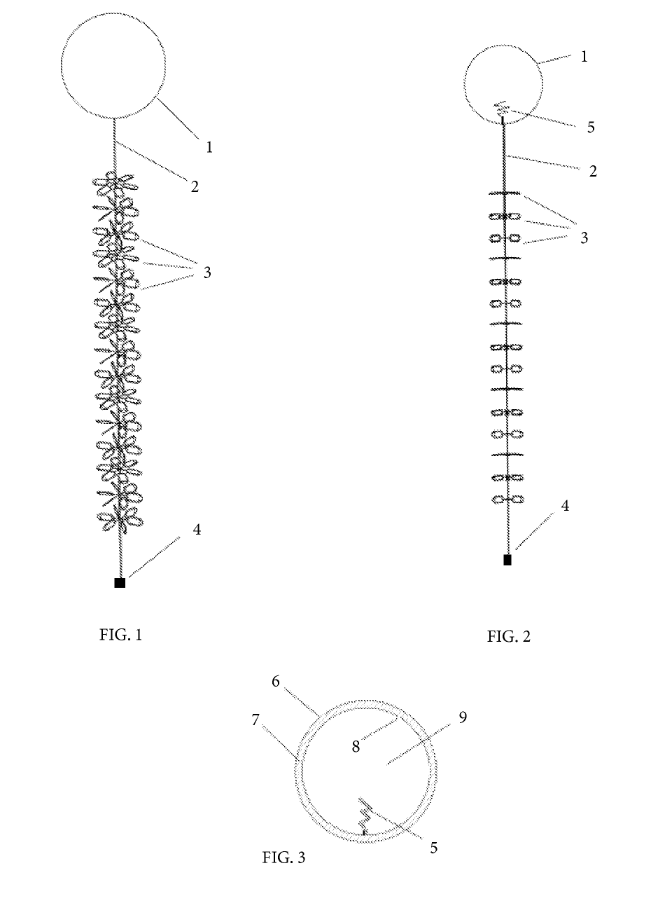

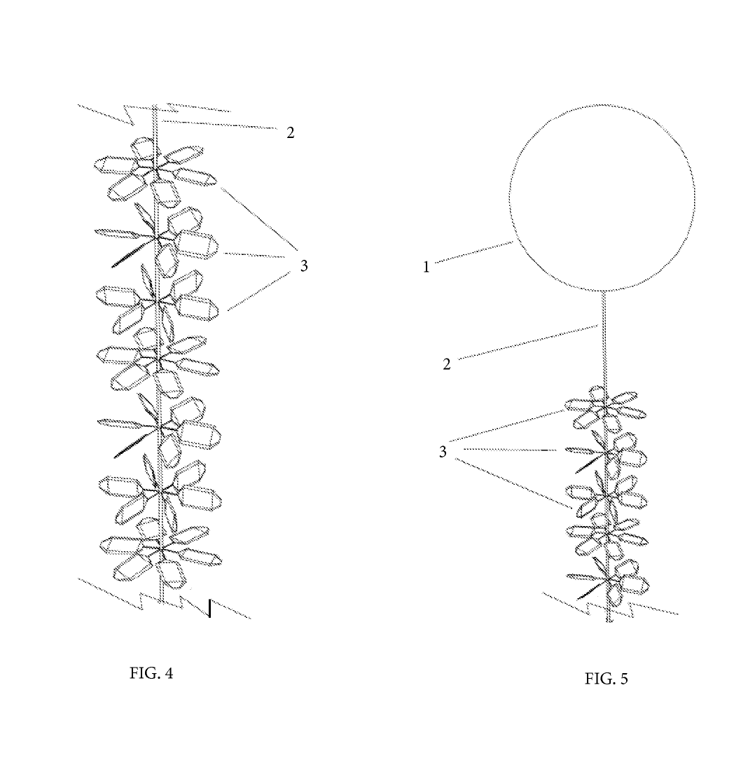

The drawings in FIGS. 1, 2, 3, 4 and 5 describe our invention. Our invention comprises of a solar balloon 1 that is attached to a very long lightweight electrical wire cord 2 that also serves as the balloon string. Many very thin, flexible and lightweight solar photovoltaic sheets 3 are attached mechanically and electrically to the electrical wire cord 2 that terminates at the terminal outlet 4.

The construction of a solar balloon 1 is described in the prior art. The material used to make a solar balloon 1 comprises of sunlight absorbing or heat absorbing or infrared rays absorbing polymer material that are elastic and constitute the skin or envelope 7 of the solar balloon 1. Any polymeric material that satisfies these conditions can serve as the envelope 7 of the solar balloon 1. Examples of polymeric material used to construct the solar balloon envelope 7 include light-weight and strong synthetic fabrics such as ripstop nylon or dacron (a polyester). The solar balloon envelope fabric 7 is coated with a sealer, such as silicone or polyurethane, to make it impermeable to air. The color of the outer surface 6 of the solar balloon envelope should be a sunlight absorbing dark color, such as red, blue, violet, green or black in order to absorb the heat energy from sunlight. Furthermore, the inner surface of the solar balloon envelope 7 should be coated with a reflective layer 8 such as a very thin aluminum coated fiberglass fabric. This inner reflective surface 8 of the solar balloon allows heat energy and infrared radiation to be trapped inside the solar balloon maintaining and increasing the temperature of the air 9 inside the solar balloon. We prefer a solar balloon envelope with radius around 16 feet occupying a volume of 21,000 cubic feet, which can support a load of 250 Lb, which is a lifting force sufficient to lift the solar photovoltaic sheet array 3 into the sky.

The electrical wire cord 2 should be made as lightweight as possible while possessing mechanical strength and durability. Electrical cords of different diameters, weight, and mechanical properties are available commercially, and those skilled in the art will be able to choose the appropriate one for our invention. We prefer an electrical wire cord 2 that is 100 feet long, which will allow the solar balloon 1 to ascend 100 feet into the atmosphere. We prefer an electrical wire gauge size of 14, which has a copper wire diameter of 2 mm, which can support 120 pound nominal load, and which only weigh a few pounds. When two of these electrical wires are combined to form the electrical cord 2, it can support a nominal load of 240 pound. The electrical terminal outlet 4 at the far end of the electrical cord 2 is a typical terminal outlet prevalent in the solar industry, and those skilled in the art will be able to obtain it commercially. The heating element 5 inside the solar balloon 1 which is connected to the electrical cord 2 can also be obtained commercially. There is a variety of heating element to choose from and those skilled in the art will be able to choose a heating element 5 that will fulfill the requirement of heating the air 9 inside the solar balloon 1.

The solar photovoltaic flexible sheets 3 are very thin and light weight. These photovoltaic sheets 3 are available commercially from company such as Alta Devices Inc in Sunnyvale, Calif., which has a company website at http://www.altadevices.com/. Those skilled in the art will be able to electrically and mechanically integrate many of these thin flexible solar photovoltaic sheets 3 onto the electrical wire cord 2. The solar photovoltaic sheets 3 are attached to the electrical cord 2 in various directions and orientations along the length of the electrical cord 2 resulting in an array of solar photovoltaic sheets 3 depicted in the drawings. Potentially, it is possible to integrate 500 of these thin flexible solar photovoltaic sheets 3 onto a 100 feet electrical cord 2. An array of 500 of these thin flexible solar photovoltaic sheets vertically aligned will produce an enormous amount of electricity from solar energy, providing a practical solution to the world's demand for clean renewable energy. It is also possible to use a longer electrical cord with length extending to 200 feet or more, in which case the balloon can carry 1000 solar sheets or more, producing even more electricity. Being vertically aligned, our solar balloon solar photovoltaic array occupies very little horizontal surface area, solving one of the most limiting factor of limited rooftop space.

The extended end at the output terminal 4 of the electrical cord 2 can be tied around a structure on the ground; the extended end at the output terminal end 4 can be tied into knots onto structures of houses, building, or even trees. The output terminal end 4 is an electrical plug connection which can be connected to inverters, to the grids, to battery charger, or to household electrical appliances. Those skilled in the art will be able to connect the electrical output terminal end 4 to various electrical devices or to the electrical grid. By simply tying the extended end of the electrical cord 2 at the terminal output end 4 around a structure on the ground, it serves to secure the solar balloon photovoltaic array at a location. This solution of mounting our solar array avoid using screws, brackets, screwdrivers, hammers, and other tools that people in poor regions of the world does not possess. This solution of mounting our solar array solves one of the most limiting factor in the solar industry by providing a simple solution that avoid using the enormous number of components in the balance of system, thereby reducing the cost of material and labor, as well as encourage adoption of our invention because of the ease of mounting our solar balloon solar array.

To provide additional buoyancy lift to the balloon 1, a heating element 5 is placed inside the balloon 1 to heat the air 9 inside the balloon in order to provide greater lift. The electricity generated from the solar photovoltaic sheets array 3 is partially channeled into the heating element 5 inside the balloon to provide this additional heating. The solar balloon 1 is heated by two sources. First, the air 9 inside the solar balloon 1 is heated by direct sunlight incident onto the outer surface 6 of the balloon envelope 7. Second, the air 9 inside the solar balloon is also heated by a heating element 5 inside the balloon; the solar photovoltaic sheets array 3 provides a portion of its electricity generated to the heating element 5. Together, these two sources of heating the air 9 inside the solar balloon 1 provides greater buoyancy in order to lift a greater number of solar photovoltaic sheets array 3. The air 9 inside the solar balloon can comprise of ordinary air molecules, or it can be comprised of a noble gas, such as helium. In the case of using helium, which is lighter than air, the helium inert gas 9 will further increase the buoyancy of the solar balloon. However, we prefer to use ordinary air 9, because ordinary air is widely and freely available.

The solar balloon photovoltaic array can be easily mounted and deployed. First, the solar balloon 1 is partially inflated to half the volume capacity of the solar balloon. Second, the extended end of the electrical cord at the terminal output end 4 is tied around a structure on the ground surface, which serves to securely attach the solar balloon 1 to a specific location on the ground. For example, the terminal end 4 can be tied around a wooden beam, a column, or any other structure of a house. This is the simplest way and most economical way to mount our solar balloon photovoltaic array. Third, the half inflated solar balloon 1 with the solar photovoltaic sheet array 3 which is integrated onto the electrical cord 2 is spread onto the ground under direct sunlight. Fourth, we wait for the sunlight to heat up the solar balloon 1 via direct sunlight impinging onto the dark color outer surface 6 of the solar balloonl. Furthermore, the solar photovoltaic array 3 will also provide solar generated electricity to the heating element 5 inside the solar balloon 1 to heat up the air 9 inside the solar balloon 1 to provide additional buoyancy lift beyond the direct heating by the sunlight. The combination of direct sunlight on the outer surface 6 heating the air inside the solar balloon 1 and the heating element 5 powered by solar electricity from the solar photovoltaic array 3 will increase the temperature of the air 9 inside the solar balloon 1 which will expand the air to fully inflate the solar balloon 1, increasing the buoyancy lifting force of the solar balloon 1 by the Archimedes principle. When the solar balloon 1 is fully inflated by the hot air 9 inside it, the solar balloon will rise into the atmosphere and lift the electrical cord 2 which carries the solar photovoltaic sheet array 3 with it into the sky. The reflective inner surface 8 of the solar balloon will help trap the heat energy inside the balloon to maintain the high temperature of the air 9 inside the balloon. The solar photovoltaic array 3 will be vertically aligned in the sky absorbing sunlight and generating electricity from solar energy. Most of this solar electricity will be conducted through the electrical wire cord 2 to the terminal output 4 at the end of the electrical wire cord on the ground surface which will be used to provide solar electricity for household consumption. A portion of the electricity will be used to power the heating element 5 inside the balloon to maintain the hot temperature of the air inside the solar balloon in order to sustain a buoyancy lifting force sufficient to lift the solar photovoltaic sheet array 3 and maintain the entire photovoltaic array in the sky indefinitely as long as the sun is providing sufficient solar energy during the day. In the night time, the air inside the solar balloon will cool down, and the solar balloon will start to deflate and descend. After it descends to the ground, the solar balloon can be fully deflated and rolled up into a small compact volume for storage. The solar photovoltaic sheet array with the electrical cord can also be rolled up into a small compact volume along with the solar balloon, since the entire invention is flexible and light weight. The next morning, the solar balloon photovoltaic array can be deployed again.

Our invention provides major advantages and improvements over the prior art. First, our invention is light weight, easily transportable, and easily stored. The solar balloon photovoltaic array can be easily deflated and folded up into a small volume for storage and transportation. The number of components in the balance of system is much fewer than conventional flat solar panel in the prior art. Having fewer components decreases the weight of our solar array invention. Second, our invention has a lower cost of production because of its fewer components. Third, our invention is much easier to install and mount because all that is required to mount our solar array is to tie the terminal output end 4 of the electrical cord 2 around any structure on the ground in order to secure the solar balloon photovoltaic array at a particular location. Fourth, our solar balloon photovoltaic array occupies very little surface area on the ground since the solar photovoltaic sheets 3 are aligned and arrayed in a vertical direction into the atmosphere.

It is the objective of our invention to provide solar generated electricity to third world countries in a device that is affordable, easily transportable, as well as occupying very little surface area, and which can generated enormous amount of solar electricity. Third world countries, developing countries, or very poor regions of the world require a source of electricity that is economical and easily adaptable to their different environments. Our invention satisfy all these criteria and we hope that those skilled in the art will be able to practice our invention in order to provide much needed clean solar generated electricity to poor regions of the world.

We claim a solar balloon photovoltaic array comprising of:

1. An array of very light weight, thin and flexible solar photovoltaic sheets mechanically and electrically attached to a long electrical wire cord which is securely attached to a solar balloon which is powered by solar energy in the form of direct heating from sunlight and electrical heating from a portion of the electricity generated from the solar photovoltaic sheet array; with
said solar photovoltaic sheets oriented in various direction along the length of said electrical cord; with
said electrical wire cord attached to said solar balloon at one end; with
said electrical wire cord terminating into an electrical output terminal at the other end; with
said electrical wire cord electrically connected to a heating element inside said solar balloon;
with said solar balloon comprising of a polymeric envelope that has an outer surface that can absorb direct sunlight to heat up the air inside said solar balloon to provide buoyancy lift; with
said polymeric envelope of said solar balloon that has an inner surface that is coated with a reflective coating to reflect and trap the heat inside said solar balloon to maintain buoyancy lift; with
said heating element inside said solar balloon that also heat up the air inside said solar balloon to provide additional buoyancy lift; with
said solar photovoltaic sheet array generating electricity through the photoelectric or photovoltaic effects from converting sunlight into electricity; with
said electricity generated by said array of photovoltaic sheets conducted along said electrical wire cord to said output terminal at the end of said electrical wire cord to provide electricity for household consumption; with said solar photovoltaic sheet array also providing a portion of its electricity to said heating element inside said solar balloon to heat the air inside said solar balloon to provide more buoyancy lift to said solar balloon; with
said terminal end of said electrical wire cord capable of being secured to a structure on the ground surface in order to secure said solar balloon to a fix location.

2. A method of launching and mounting said solar balloon photovoltaic sheet array into the atmosphere, comprising of:
partially inflating said solar balloon with air to half the volume capacity of said solar balloon;
spreading said solar balloon and said solar photovoltaic sheet array which is attached to the long electrical wire cord on the ground under direct sunlight;
allowing direct sunlight to be absorbed by the outer surface of said solar balloon envelope in order to heat up the air inside said solar balloon to provide buoyancy lift;
allowing sunlight to incident onto the solar photovoltaic sheet array in order to convert sunlight into electricity; with
said solar generated electricity used to power the heating element inside said solar balloon to heat up the air inside said solar balloon to provide buoyancy lift;
with said solar balloon fully inflated and lifted up into the atmosphere by the hot air inside said solar balloon, which lift said long electrical cord that carry the solar photovoltaic sheet array;
with said solar photovoltaic sheet array producing electricity from sunlight;
with said solar generated electricity conducted by said electrical wire cord to the output terminal for household consumption;
with a portion of said solar generated electricity generated by said solar photovoltaic sheet array used to power said heating element inside said solar balloon in order to heat up the air inside said solar balloon to maintain sufficient buoyancy lifting force; with
said solar balloon being maintained in the atmosphere by the power of the sun, carrying the solar photovoltaic sheet array for converting sunlight to electricity during the daytime.
